(19) United States
(12) Patent Application Publication
(10) Pub. No.: US 2015/0255480 A1
(43) Pub. Date: Sep. 10, 2015

(54) Method to Improve Charge Trap Flash Memory Top Oxide Quality

(71) Applicant: Spansion LLC, Sunnyvale, CA (US)

(72) Inventors: Tung-Sheng CHEN, Cupertino, CA (US); Shenqing FANG, Fremont, CA (US); Inkuk KANG, San Jose, CA (US)

(73) Assignee: Spansion LLC, Sunnyvale, CA (US)

(21) Appl. No.: 14/270,700

(22) Filed: May 6, 2014

Related U.S. Application Data
(63) Continuation-in-part of application No. 13/680,726, filed on Nov. 19, 2012, now Pat. No. 8,835,277.
Application No. 13/680,726 is a continuation of application No. 61/708,133, filed on Oct. 1, 2012.

(30) Foreign Application Priority Data
Mar. 13, 2013 (US) PCT/US2013/030691

(51) Int. Cl. H01L 27/115; H01L 21/311; H01L 29/423; H01L 29/06; H01L 29/792; H01L 21/28; H01L 29/66; H01L 21/762; H01L 29/51

(52) U.S. Cl. CPC H01L 27/11568; H01L 21/76224; H01L 21/31116; H01L 21/31111; H01L 29/4234; H01L 29/513; H01L 29/518; H01L 29/792; H01L 21/28282; H01L 27/11565; H01L 29/66833; H01L 29/0649

(57) ABSTRACT

A semiconductor processing method to provide a high quality top oxide layer in charged-trapping NAND and NOR flash memory. The top oxide layer of NAND and NOR flash memory determines array device performance and reliability. The method described overcomes the corner thinning issue and the poor top oxide quality that results from the traditional oxidation approach of using pre-deposited silicon-rich nitride.

### BACKGROUND

1. Field

This invention relates generally to memory fabrication, and more particularly to a semiconductor processing method for flash memory fabrication.

2. Background Art

The semiconductor market has been undergoing extensive growth over the past few decades. This trend is expected to continue for the foreseeable future since a large portion of this market is the memory segment. The memory segment can be broadly categorized into two classes, namely volatile memory and non-volatile memory. Volatile memory such as SRAM and DRAM lose their data content when the power supply is removed. In contrast, non-volatile memories such as EEPROM and flash memories maintain their data content after the power supply has been removed.

Non-volatile memories offer particular advantages, and thereby support a wide range of applications including computer, automotive and consumer electronic devices. Flash memory is a non-voltage memory that can be electrically erased and reprogrammed. In fact, flash memory has undergone an explosive market growth that has in particular been driven by cellular telephones, memory cards, flash drives and other types of portable data storage devices. Indeed, with the need to support persistent data storage in portable devices, it is clear that the flash memory will continue to grow at an ever increasing rate. Further, the market place will demand flash memory designs that support lower cost and higher performance, including higher densities of storage.

The basic concept of a charge trap flash memory cell is that of a charge trap layer in a semiconductor transistor. The electrical isolation of the charge trap layer is accomplished by surrounding it with dielectric material, such as an oxide. Typically, charge trap flash memory cells use two oxide layers, a “bottom” oxide layer and a “top” oxide layer. The top oxide layer in a flash memory cell plays a key role in determining flash memory cell performance and reliability.

### BRIEF SUMMARY

Degraded flash memory cell performance can result from top oxide issues such as “corner thinning” and poor quality. What is needed is a processing approach by which the top oxide layer can be manufactured while maintaining satisfactory flash memory cell performance and reliability.

In one embodiment, a fabrication method includes forming a plurality of trench isolation regions on a substrate. A tunneling dielectric layer is also formed on the substrate, following by a charge trapping layer and a first sacrificial layer. A portion of the first sacrificial layer and charge trapping layer are removed on the tops of mesas associated with the trench isolation regions. The resulting wings in the charge trapping layer are recessed back to approximately the bottom of the charge trapping layer, followed by the removal of the first sacrificial layer. In this application, the term “wings” means the appendages (or tips) of the charge trapping layer that are adjacent to the mesas. Next, a blocking dielectric layer is formed on the charge trapping layer, together with a second sacrificial layer. Planarization removes portions of the blocking dielectric layer and second sacrificial layer, followed by oxidization of the blocking dielectric layer that results in the final material for the blocking dielectric layer. A gate region is then formed on the blocking dielectric layer.

The features and advantages of the current invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 illustrates a block diagram of a memory cell array structure, in accordance with an embodiment of the current invention.

FIGS. 2A and 2B illustrates a top oxide layer of a memory cell array structure using a standard fabrication process.

FIGS. 3A through 3H show a flow diagram of a method of fabricating a charge trapping field effect transistor, in accordance with an embodiment of the current invention.

FIG. 4 illustrates the formation of shallow trench isolation (STI) patterning film stack, in accordance with an embodiment of the current disclosure.

FIG. 5 illustrates the formation of shallow trench isolation (STI) regions, in accordance with an embodiment of the current disclosure.

FIG. 6 illustrates the formation of the mesas, in accordance with an embodiment of the current disclosure.

FIGS. 7A through 7F illustrate the silicon-rich nitride isolation step, in accordance with an embodiment of the current disclosure.

FIG. 8 illustrates the thicker standard silicon nitride formation over the silicon-rich nitride wings, in accordance with an embodiment of the current disclosure

FIG. 9 provides a flowchart of a method that fabricates a memory flash memory cell structure with a high quality top oxide layer, according to an embodiment of the current invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

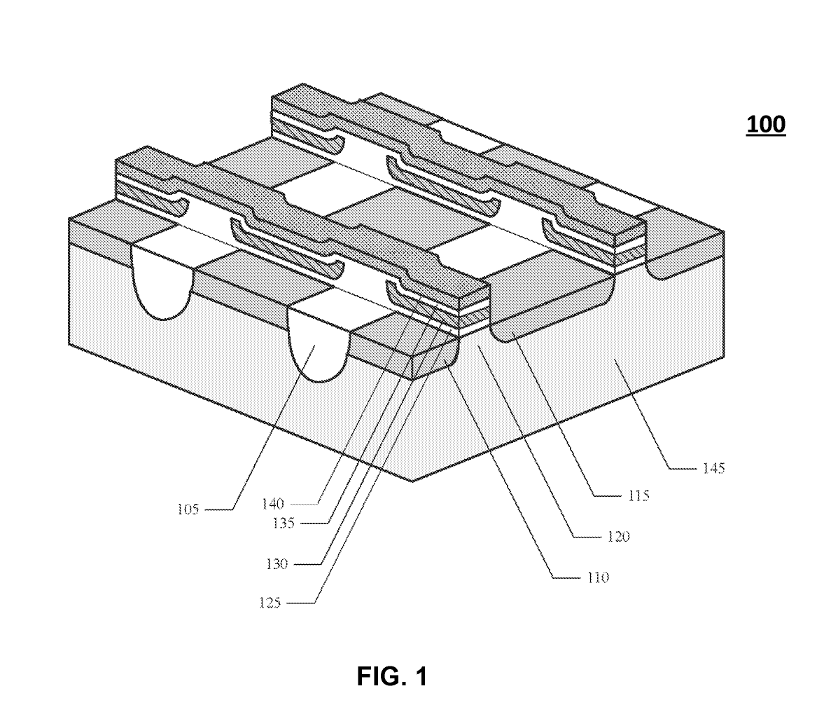

FIG. 1 illustrates a block diagram of a memory cell array structure, in accordance with an embodiment of the current invention. Referring to FIG. 1, a memory cell array may be a charge-trapping NAND (CT-NAND) memory cell array 100. However, it is noted that embodiments of the present technology may be applied to any charge-trapping FET (CT-FET) device. In one implementation, each column of CT-FETs may be separated by a shallow trench isolation (STI) region 105. Each CT-FET may include a drain region 110, a source region 115, a channel region 120, a tunneling dielectric layer 125 (also commonly referred to as a bottom dielectric layer), a charge trapping layer 130, a blocking dielectric layer 135 (also commonly referred to as a top dielectric layer), and a gate region 140. The source and drain regions 110, 115 may be semiconductor regions of the substrate 145 having a heavy doping concentration of a first type of impurity. In one implementation, the source and drain regions 110, 115 may be silicon that is heavily doped with phosphorous or arsenic. Persons of ordinary skill in the relevant arts will also recognize alternative materials can also be used, and fall within the scope of the current invention. The channel region 120 may be a semiconductor region of the substrate 145 having a moderate doping concentration of a second type of impurity, and disposed laterally between the source and drain regions 110, 115. In one implementation, the channel region 120 may be silicon that is moderately doped with boron. The tunneling dielectric layer 125 may be a dielectric layer disposed over the channel region 120 and adjacent portions of the source and drain regions 110, 115. In one implementation, the tunneling dielectric layer 125 may be silicon oxide, oxynitride, silicon oxynitride, or the like layer. The charge trapping layer 130 may be a dielectric, semiconductor or the like layer disposed between the tunneling dielectric layer 125 and the blocking dielectric layer 135. In one implementation, the charge trapping layer 130 may be a nitride, silicon-rich-nitride, or the like layer. The blocking dielectric layer 135 may be a dielectric layer disposed between the charge trapping layer 130 and the gate region 140. In one implementation, the blocking dielectric layer 135 may be a silicon oxide, oxynitride, silicon oxynitride, or the like layer. The gate region 140 may be a semiconductor or a conductor layer disposed on the blocking dielectric layer 135 opposite the charge trapping layer 130. In one implementation, the gate region 140 may be a polysilicon layer having a heavy doping concentration of the first type of impurity.

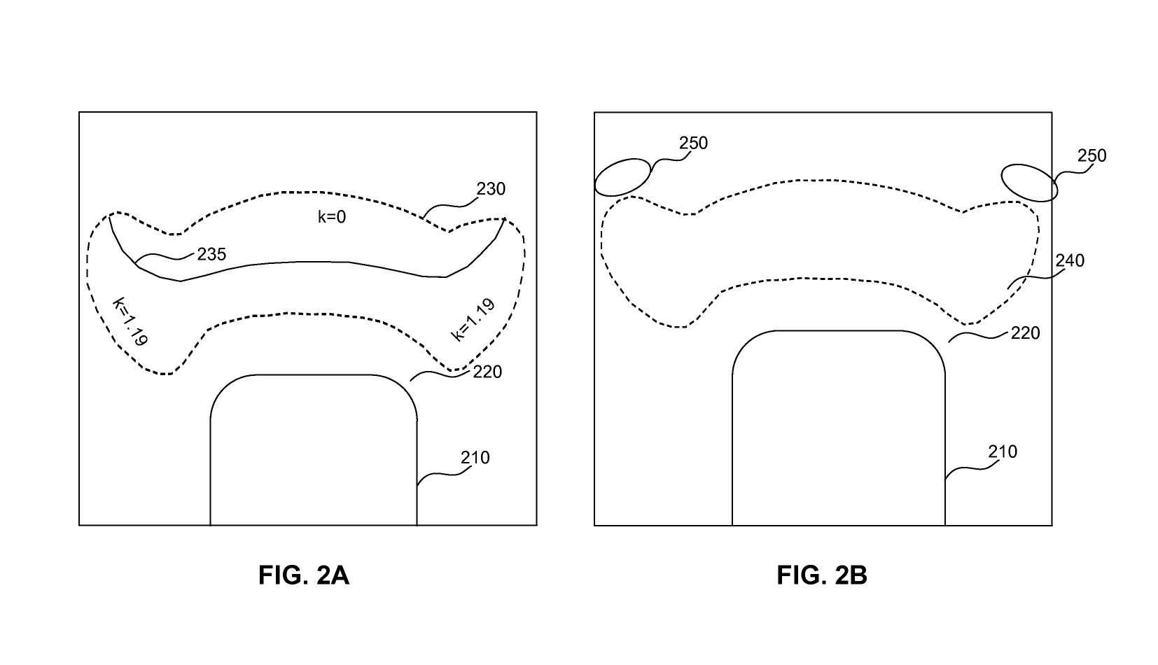

As noted above, degraded flash memory cell performance can result from top oxide issues such as “corner thinning” and poor quality. FIGS. 2A and 2B illustrate potential areas of concern for poor quality in the standard (or control) process. Referring to FIG. 2A, the source-drain pillar 210 is illustrated with the bottom oxide layer 220 shown on top. A composite nitride layer 230 forms the starting point for the charge trapping layer. Composite nitride layer 230 can be fabricated as a silicon-rich nitride sub-layer together with standard nitride layer. As shown in FIG. 2A, the silicon-rich nitride sub-layer has a coefficient of extinction (k) of 1.19, while the standard nitride sub-layer has a coefficient of extinction (k) of 1.0. For illustration purposes, dividing line 235 divides the silicon-rich nitride sub-layer from the standard nitride layer in FIG. 2A.

FIG. 2B illustrates the same semiconductor structure following the top oxide process step. The composite nitride layer 240 has shrunk as a result of the top oxide process. The standard nitride layer (k=0) produces a high quality top oxide layer. The silicon-rich nitride layer (k=1.19) produces a sub-standard top oxide layer. In FIG. 2B, the two circled areas 250 are areas where silicon-rich nitride material has been exposed to the top oxide process step, and thereby a sub-standard top oxide layer has been produced. It is therefore desirable to modify the process flow to avoid this problem.

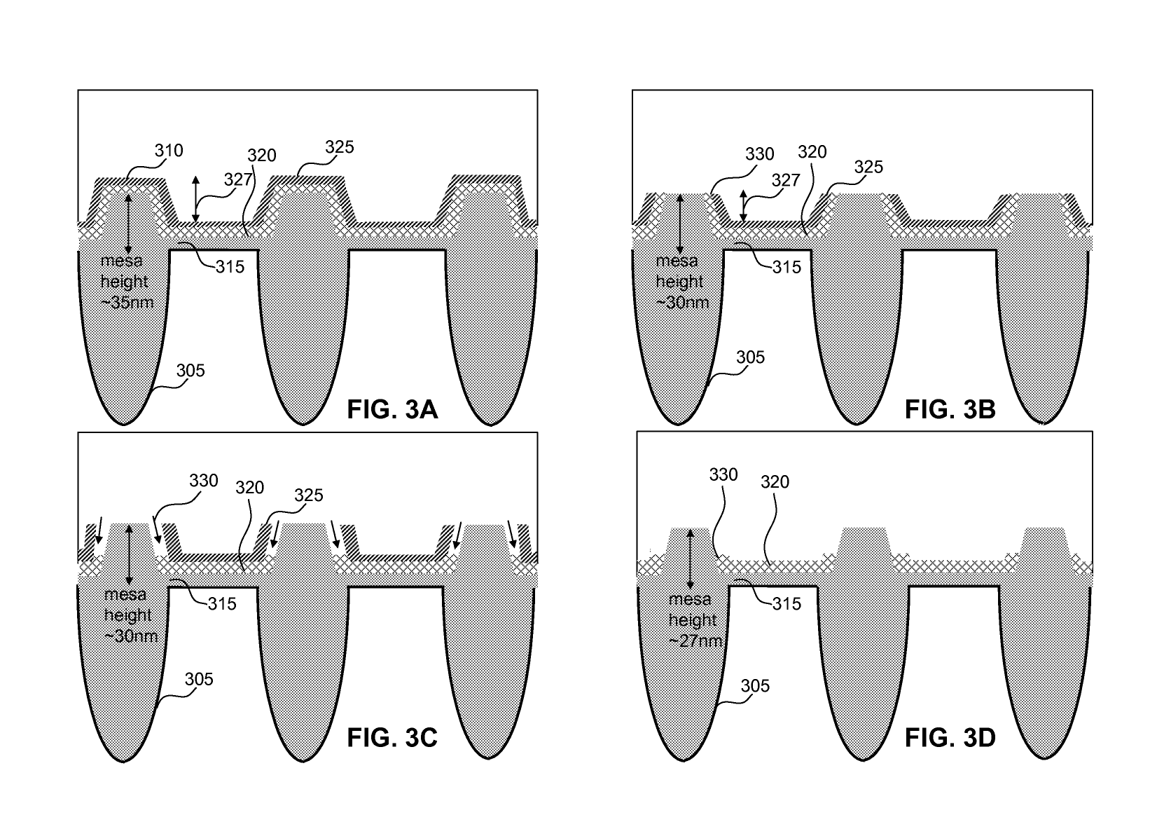

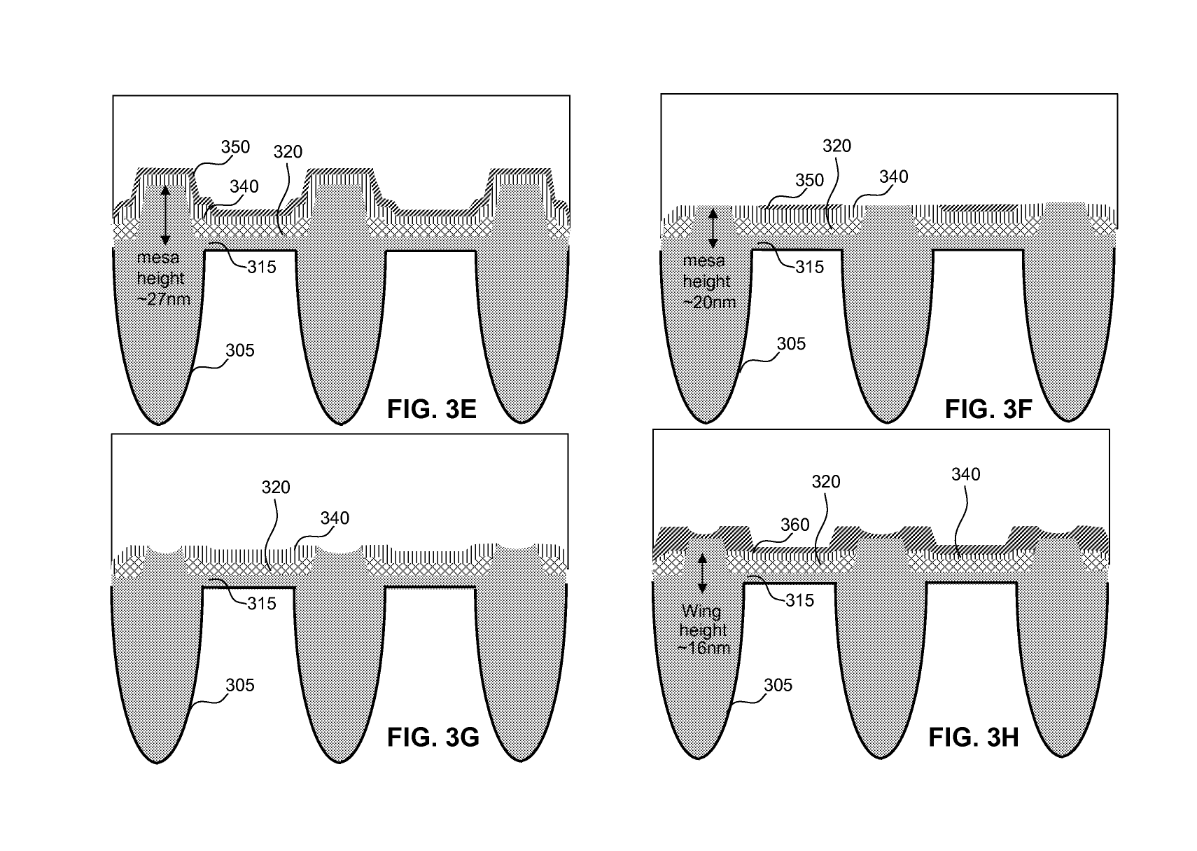

FIGS. 3A through 3H illustrate a semiconductor fabrication process that avoids the problem described in the previous paragraph, in accordance with an embodiment of the current invention. Referring to FIG. 3A, the shallow trench isolation (STI) region 305 is formed in a conventional manner, such as oxidation of the silicon crystalline substrate. Associated with each shallow trench isolation (STI) region 305 is an associated mesa 310.

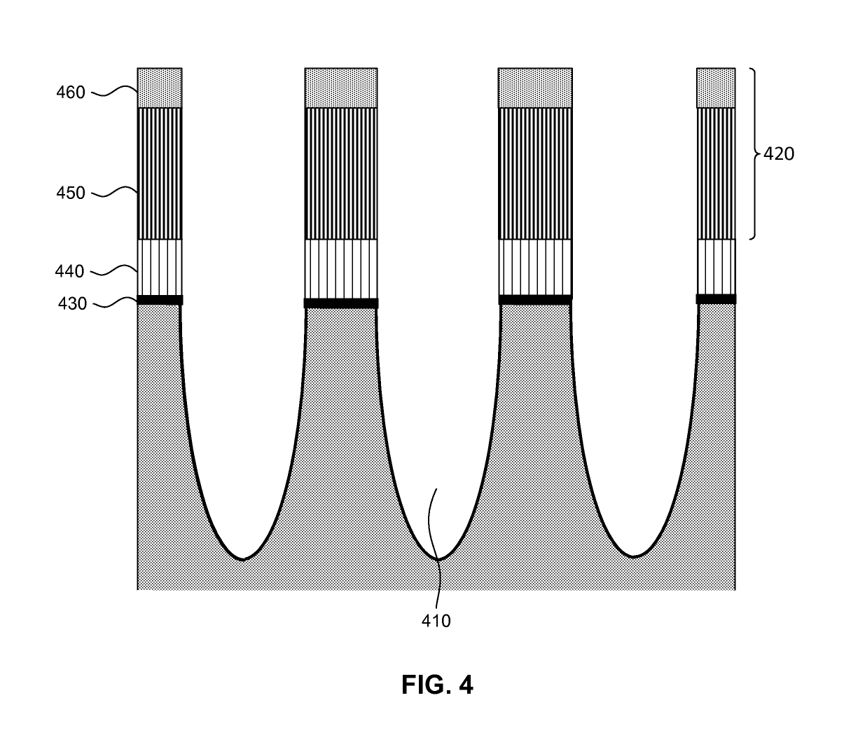

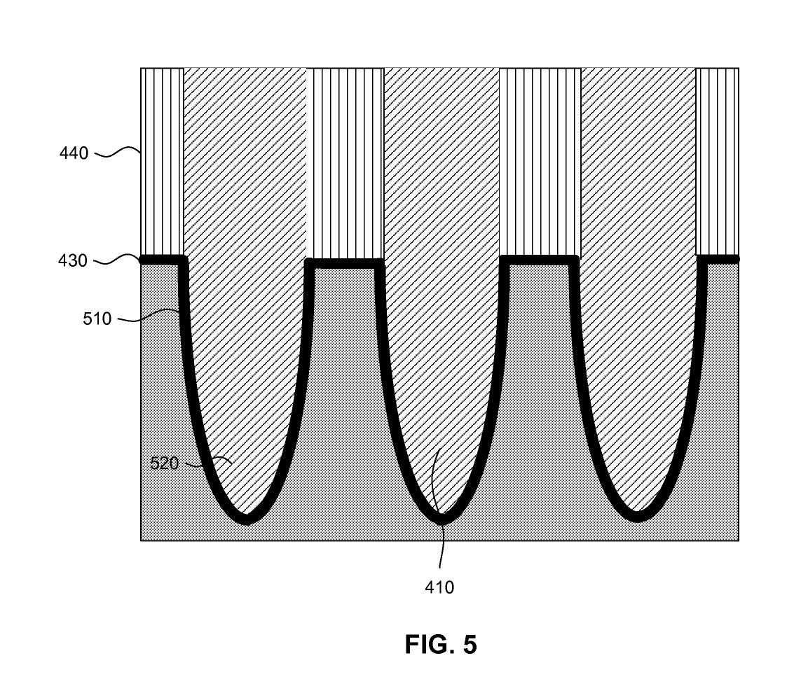

FIG. 4 illustrates one approach to the formation of shallow trench isolation (STI) regions 305. First, pad oxide layer 430 followed by nitride layer 440 are formed on top of substrate 145. The height of nitride layer 440 is determined based on the desired height of mesa 310. Next, a shallow trench isolation (STI) patterning film stack 420 is formed by the formation of amorphous carbon layer 450 on top of nitride layer 440. Subsequently, an organic bottom anti-reflective coating (BARC) layer 460 is formed on top of amorphous carbon layer 450 following by a deposition of a photoresist layer (not shown) for subsequently lithography. Using a mask with the appropriate STI pattern, the photoresist is then used to define the desired shallow trench isolation (STI) gap 410. Following development of the photoresist, shallow trench isolation (STI) gaps 410 are formed by a dry etch process, as defined by the developed photoresist. In an embodiment, shallow trench isolation (STI) gaps 410 are formed with a depth of 1500 to 2500 Angstroms.

Having defined shallow trench isolation (STI) gaps 410, the patterning film stack 420 is no longer required. The organic bottom anti-reflective coating (BARC) layer 460 and amorphous carbon layer 450 are removed, as illustrated in FIG. 5. In an exemplary embodiment, organic bottom anti-reflective coating (BARC) layer 460 and amorphous carbon layer 450 are removed through the use of a plasma etch process. This leaves nitride layer 440 placed on top of pad oxide layer 430.

Next, FIG. 5 illustrates the completion of the formation of shallow trench isolation regions 305. Shallow trench isolation regions 305 are formed by introducing liner oxide 510. In an exemplary embodiment, liner oxide 510 may be 2 to 8 nm in thickness. The introduction of liner oxide 510 is followed by a filling of the resulting shallow trench isolation (STI) gap with a suitable STI gap-fill oxide 520. In an embodiment, STI gap-fill oxide 520 may be formed using a high aspect ratio process (HARP). Following the deposition of the STI gap-fill oxide 520, a suitable process is used to smooth the top surface of the resulting substrate. In an embodiment, a chemical mechanical planarization (CMP) process is used so that the tops of nitride layer 440 and STI gap-fill oxide 520 are smoothed out.

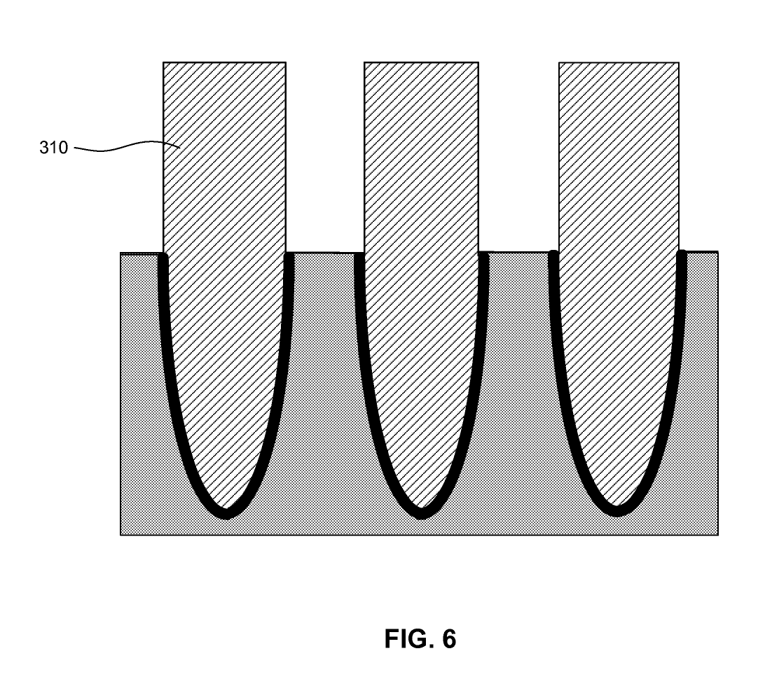

The addition of STI gap-fill oxide 520 provides the required mesa 310. FIG. 6 illustrates the removal of the intervening pad oxide layer 430 and nitride layer 440 to expose mesa 310. First, a wet etch process is used to remove nitride layer 440 without removing the underlying pad oxide layer 430. In an exemplary embodiment, the wet etch process may use hot phosphoric acid. Next, another wet etch process is used to strip the pad oxide layer 430. In an exemplary embodiment, this wet etch process may use diluted hydrofluoric acid (DHF). After application of these two wet etch processes, mesas 310 are now exposed.

Having produced mesas 310, the active area between mesas 310 now is formed. Returning to FIG. 3A, FIG. 3A illustrates the formation of three layers as part of this process. Bottom oxide layer 315 is shown as the first layer in the active layer stack. A thin silicon-rich nitride (SiRN) layer 320 is deposited over bottom oxide layer 315, followed by a first high temperature oxide (HTO) layer 325. First HTO layer 325 is a sacrificial oxide layer.

In an exemplary embodiment, with a mesa height of approximately 35 nm, the bottom oxide layer 315 is approximately 6 nm in thickness, the thin silicon-rich nitride layer 320 is approximately 9 nm in thickness, and the first HTO layer 325 is approximately 5 nm in thickness. The height 327 above the neighboring valleys (where the active area is located) is 29 nm in this exemplary embodiment.

Having laid down bottom oxide layer 315 and thin silicon-rich nitride layer 320, the individual portions of thin silicon-rich nitride layer 320 in the active area need to be isolated from each other. This process may be referred to as silicon-rich nitride (SiRN) isolation, and may be accomplished using a SiRN isolation mask together with an appropriate etch. Referring now to FIG. 3B, SiRN isolation may be accomplished by an oxide/nitride (ON) cut process. Two alternative approaches may be deployed to provide the first oxide/nitride (ON) cut. The choice of these alternative approaches may be made based on available semiconductor processing capabilities.

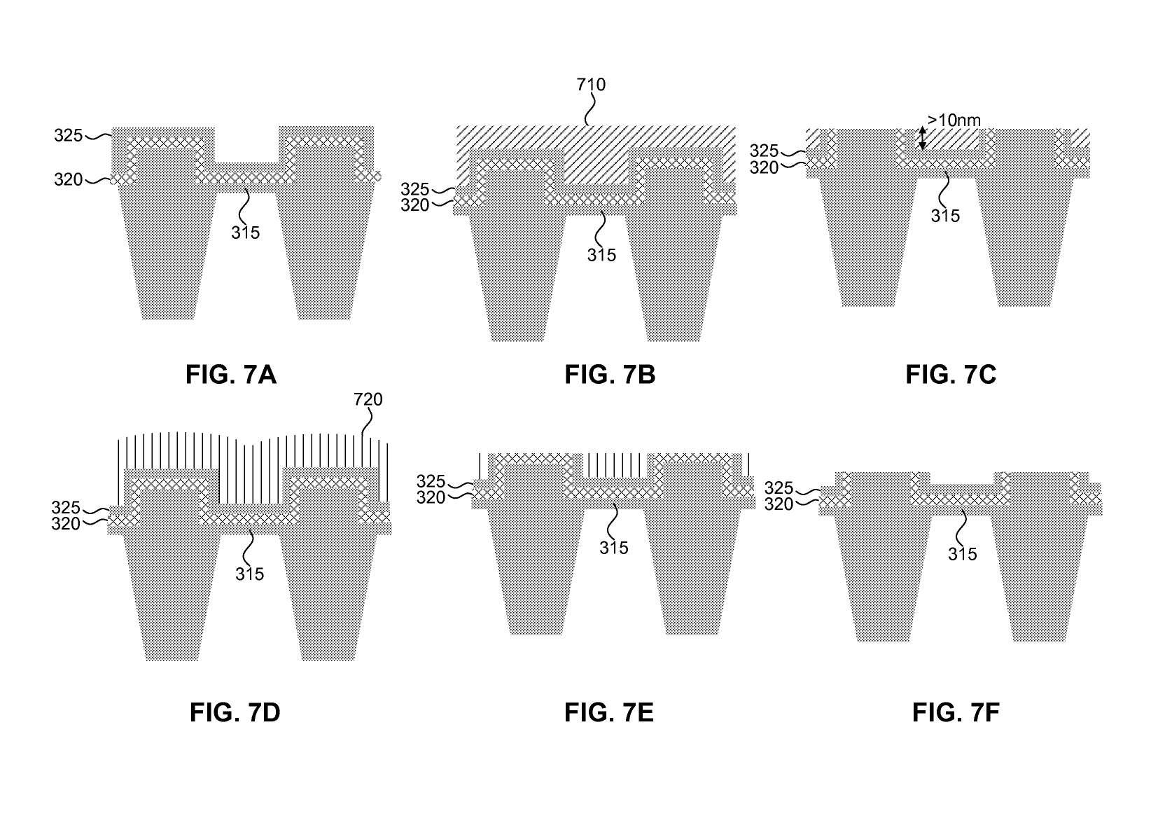

FIGS. 7A through 7C illustrate a first exemplary embodiment of the ON cut process. As FIG. 7A illustrates, a thin sacrificial top oxide layer 325 has been deposited on top of the thin silicon-rich nitride layer 320. Next, an organic BARC coating 710 is deposited, as shown in FIG. 7B. Next, FIG. 7C illustrates the result of a dry etch process and BARC strip process that removes the organic BARC coating, the thin sacrificial top oxide layer as well as the thin silicon-rich nitride layer 320 so that SiRN isolation occurs. As FIG. 7C illustrates, in an exemplary dry etch process, a minimum of 100 Angstroms of BARC coating remains over the portion of the thin sacrificial top oxide layer over the active region.

FIGS. 7D through 7F illustrate a second exemplary embodiment of the ON cut process. As FIG. 7D illustrates, the first step may be the deposition of a thick sacrificial top oxide layer 720 on top of the thin silicon-rich nitride layer 320. In certain embodiments, the first HTO layer 325 (sacrificial oxide) may or may not be needed. Next, FIG. 7E illustrates the result when the thick sacrificial oxide layer 720 is polished back using, for example, a chemical mechanical planarization (CMP) process. As a result of the CMP process, the oxide is completely removed, thereby leaving the portion of the thin silicon-rich nitride layer 320 on the mesa exposed. Next, FIG. 7F illustrate the result of a dry etch process that removes the exposed thin silicon-rich nitride layer 320 to thereby “isolate” the individual portions of thin silicon-rich nitride layer 320 in the active area.

Referring back to FIG. 3B, using either embodiment of the ON cut step process results in removal of the tops of the mesa to the level necessary to include removal of the thin silicon rich nitride layer 320 from the top of the mesas. In an exemplary embodiment, the height 327 of mesa 310 above HTO layer 325 is reduced from approximately 29 nm to approximately 13 nm, as is illustrated in moving from FIG. 3A to FIG. 3B. The resulting height of the mesa is now reduced to approximately 30 nm in this example.

Referring now to FIG. 3C, the resulting wings 330 of the thin silicon-rich nitride layer 320 are recessed back to a level commensurate with a remainder of the silicon rich-nitride layer. As noted above, in this application, the term “wings” means the appendages (or tips) of the thin silicon-rich nitride layer 320 (charge trapping layer) that are adjacent to the mesas. In an exemplary embodiment, the recess reduction is approximately 11 nm. In an exemplary process step, a wet etch process can be used, such as application of phosphoric acid or its equivalent. As a result of this process the mesa height remains approximately constant. In an exemplary embodiment, the mesa height remains at 30 nm.

Referring now to FIG. 3D, the first HTO layer 325 is now removed, as its function of protection of the silicon-rich nitride layer 320 has now been accomplished and no longer required. In an exemplary process step, a wet etch process can be used to remove HTO layer 325. In removing the first HTO layer 325, a portion of the mesa height is also removed. In an exemplary embodiment, the mesa height is reduced to approximately 27 nm.

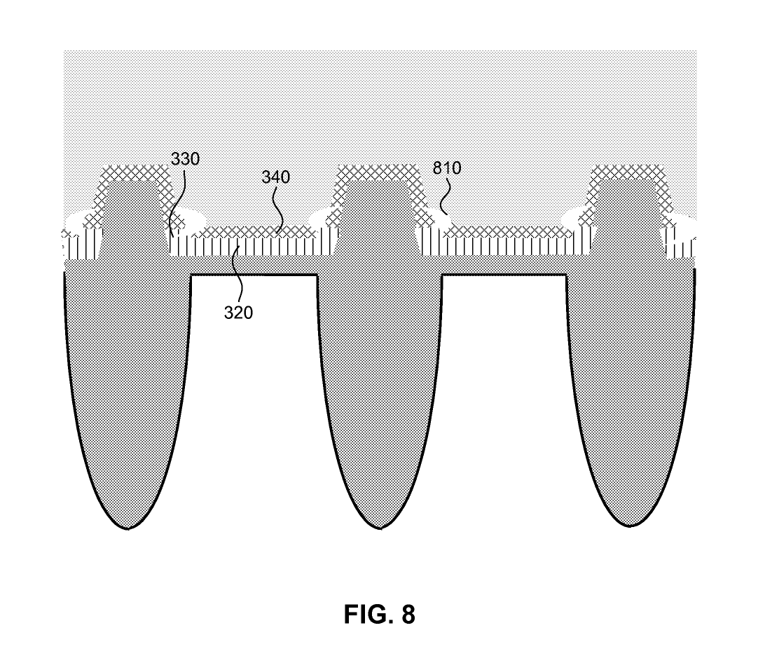

Referring now to FIG. 3E, a cap standard silicon nitride layer 340 is overlaid on top of the device. The term “standard silicon nitride” (SiN) is used to distinguish this material from a silicon-rich nitride (SiRN) material. The standard silicon nitride layer 340 may be formed using an atomic layer deposition process. FIG. 8 illustrates that standard silicon nitride layer 340 is thicker on the silicon-rich nitride wings 330 due to the topography. The greater thickness ensures that there is sufficient standard silicon nitride between silicon-rich nitride wings 330 and a subsequent top oxide layer 360. In one embodiment, the top oxide layer 360 can be formed by oxidization of portions of standard silicon nitride layer 340 to thereby leave residual standard silicon nitride remaining on the mesa. This results in a better quality of oxide. In another embodiment and referring back to FIG. 3E, on top of the cap standard silicon nitride layer 340 is also overlaid a second HTO layer 350. In an exemplary embodiment, the cap standard silicon nitride layer 340 is 4 nm thick, and the second HTO layer 350 is 2 nm thick.

Referring now to FIG. 3F, the mesa height is now recessed using a second ON cut down to the underlying oxide and to leave a uniform top layer to the device. In an exemplary embodiment, the second ON cut step can be a dry etch process. In an exemplary embodiment, the mesa height has been reduced to 20 nm.

Referring now to FIG. 3G, the remaining second HTO layer 350 is now removed. In an exemplary embodiment, a wet etch process is used to remove the remaining HTO layer 350. As a result of the above steps, the silicon-rich nitride layer is not problematically exposed to subsequent process steps, and therefore the prospect of a resulting low quality oxide is reduced.

Finally, referring to FIG. 3H, the top oxide layer 360 is formed. In this step, the top layer is standard silicon nitride 340, which is converted to silicon oxide 360. Following this step, the oxide/nitride/oxide (ONO) layer is now complete, and ready for subsequent finishing steps such as polysilicon layer deposition, gate deposition and the like. In an exemplary embodiment, the wing height of the thin silicon rich nitride layer 320 is approximately 16 nm.

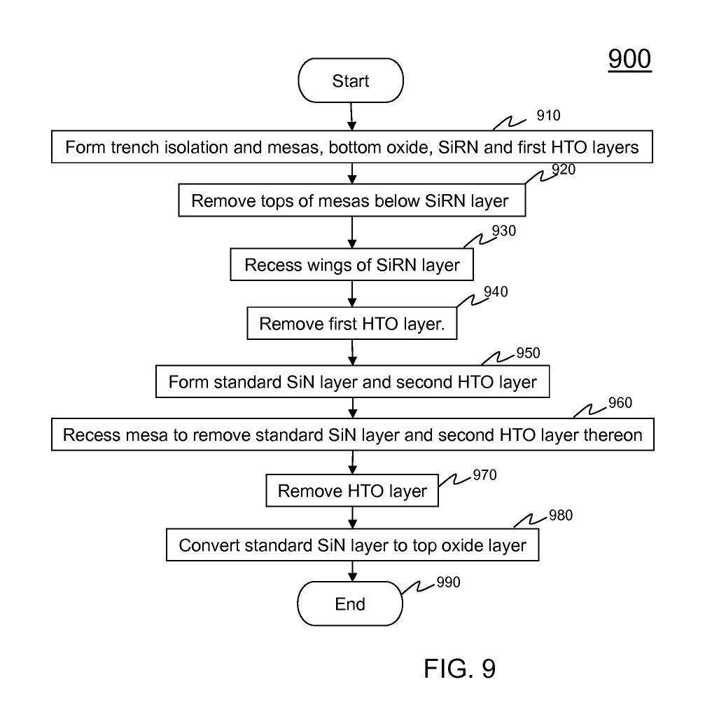

FIG. 9 provides a flowchart of a method that fabricates a memory flash memory cell structure with a high quality top oxide layer, according to an embodiment of the current invention.

The process begins at step 910. In step 910, isolation trenches 305 and associated mesas 310 are formed. Bottom oxide layer 315, SiRN layer 320 and first HTO layer 325 are also formed.

In step 920, the tops of the mesas are removed to below the SiRN layer 320.

In step 930, the wings 330 of SiRN layer 320 are recessed to approximately a level commensurate with a remainder of SiRN layer 320.

In step 940, the first HTO layer 325 is removed.

In step 950, standard SiN layer 340 and second HTO layer 350 are formed.

In step 960, the mesa is recessed to remove standard SiN layer 340 and second HTO layer 350.

In step 970, the second HTO layer 350 is removed.

In step 980, the standard SiN layer 340 is converted to top oxide layer 360.

At step 990, method 900 ends.

The benefit of the above fabrication approach has been validated via experimentation. A large number of devices fabricated using the above approach have been tested to determine their ability to maintain the storage charge following programming. In one set of experiments, two sets of devices were fabricated. One set of devices were manufactured using the baseline fabrication process. The second set of devices was fabricated using the above approach. Both sets of devices were tested to determine their ability to maintain the storage charge under various stress conditions. Using program pass voltages (Vpass) of 7 V and 8 V, the ability for the sets of devices to maintain their charge was monitored with program verify voltages of 2.0 V and 2.4 V. In all cases, the standard (or control) approach revealed a portion of the devices lost charge due to inferior top quality oxide. In all cases, the devices fabricated using the above approach revealed no flash memory devices showed evidence of loss of charge, thereby validating the above approach.

As the above discussion indicates, the SiRN layer 340 is used to provide the charge trapping layer 130. The coefficient of extinction (k) is used to characterize the SiRN layer 340. Although the SiRN layer 340 can be a single layer, a composite layer approach can also be used. The bottom of such a composite layer would have a high k (for example, k=1.19) while the top of such a composite layer would have a k value of approximately 0, the value associated with standard SiN material. The choice of the proper value of k represents a compromise between competing factors. For example, a larger k-value results in a faster program/erase cycle, but the resulting device will saturate faster and pose a rougher interface with the standard SiN layer. Conversely, a lower k-value results in difficulties in erasure, and in fact a k-value of zero (corresponding to standard SiN material) cannot be erased by Fowler-Nordheim (FN) tunneling. Suitable values of k for the SiRN layer can range between 0.9 through 1.19, depending on the other device material choices and dimensions.

It is to be appreciated that the Detailed Description section, and not the Summary and Abstract sections, is intended to be used to interpret the claims. The Summary and Abstract sections may set forth one or more but not all exemplary embodiments of the current invention as contemplated by the inventor(s), and thus, are not intended to limit the current invention and the appended claims in any way.

The current invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the current invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the current invention should not be limited by any of the above-described exemplary embodiments, but should be defined only in accordance with the following claims and their equivalents.

The claims in the instant application are different than those of the parent application or other related applications. The Applicant therefore rescinds any disclaimer of claim scope made in the parent application or any predecessor application in relation to the instant application. The Examiner is therefore advised that any such previous disclaimer and the cited references that it was made to avoid, may need to be revisited. Further, the Examiner is also reminded that any disclaimer made in the instant application should not be read into or against the parent application.

What is claimed is:

1. A method comprising:
disposing a first region comprising a plurality of trench isolation regions on a substrate,
wherein each trench isolation region includes mesas having sidewalls and tops;
disposing a tunneling dielectric layer on the first region;
disposing a charge trapping layer over the tunneling dielectric layer;
disposing a first sacrificial layer over the charge trapping layer;
first selective removing the first sacrificial layer and the charge trapping layer from the tops of the mesas to thereby result in wings in the charge trapping layer adjacent to the mesas;
recessing the wings down to a level commensurate with a remainder of the charge trapping layer;
removing the first sacrificial layer;
disposing a standard silicon-nitride (SiN) layer over the charge trapping layer and exposed mesas;
oxidizing portions of the standard SiN layer to form a blocking dielectric layer on the charge trapping layer; and
disposing a gate region on the blocking dielectric layer.

2. The method of claim 1, further comprising prior to the oxidizing:
disposing a second sacrificial layer over the standard SiN layer;
second selective removing the second sacrificial layer and the standard SiN layer to result in a flat structure; and
removing remaining portions of the second sacrificial layer.

3. The method of claim 1, wherein the tunneling dielectric layer comprises silicon dioxide.

4. The method of claim 1, wherein the charge trapping layer comprises silicon-rich nitride (SiRN).

5. The method of claim 4, wherein the SiRN has an extinction coefficient in the range of approximately 0.9 through 1.19.

6. The method of claim 1, wherein the blocking dielectric layer comprises silicon oxide.

7. The method of claim 1, wherein the first sacrificial layer comprises a high temperature oxide layer.

8. The method of claim 1, wherein the first selective removing includes using dry etching.

9. The method of claim 1, wherein the recessing includes using wet etching.

10. The method of claim 1, wherein the removing the first sacrificial layer includes using wet etching.

11. A charge trapping flash memory device, comprising:
a semiconductor substrate comprising a plurality of trench isolation regions, wherein each trench isolation region includes mesas having sidewalls and tops;
a tunneling dielectric layer having a lower surface, wherein the tunneling dielectric layer is formed on the upper surface of the substrate;
a charge trapping layer over the tunneling dielectric layer, wherein the charge trapping layer comprises one or more wings adjacent to the mesas;
a blocking dielectric layer formed over the charge trapping layer; and
a gate formed on the blocking dielectric layer.

12. The charge trapping flash memory device of claim 11, wherein the tunneling dielectric layer comprises silicon dioxide.

13. The charge trapping flash memory device of claim 11, wherein the charge trapping layer comprises silicon-rich nitride (SiRN).

14. The charge trapping flash memory device of claim 13, wherein the SiRN has an extinction coefficient in the range of approximately 0.9 through 1.19.

15. The charge trapping flash memory device of claim 11, wherein the blocking dielectric layer comprises silicon oxide.

16. The charge trapping flash memory device of claim 11, wherein the gate comprises polysilicon.

17. A charge trapping flash memory apparatus, comprising:
an array of semiconductor device cells, wherein each semiconductor device cell comprises:
a semiconductor substrate comprising a plurality of trench isolation regions, wherein each trench isolation region includes mesas having sidewalls and tops;
a tunneling dielectric layer having a lower surface, wherein the tunneling dielectric layer is formed on the upper surface of the substrate;
a charge trapping layer over the tunneling dielectric layer, wherein the charge trapping layer comprises one or more wings adjacent to the mesas;
a blocking dielectric layer formed over the charge trapping layer; and
a gate formed on the blocking dielectric layer.

18. The charge trapping flash memory apparatus of claim 17, wherein the tunneling dielectric layer comprises silicon dioxide.

19. The charge trapping flash memory apparatus of claim 17, wherein the charge trapping layer comprises silicon-rich nitride (SiRN).

20. The charge trapping flash memory apparatus of claim 19, wherein the SiRN has an extinction coefficient in the range of approximately 0.9 through 1.19.

21. The charge trapping flash memory apparatus of claim 17, wherein the blocking dielectric layer comprises silicon oxide.

22. The charge trapping flash memory device of claim 17, wherein the gate comprises polysilicon.
